(19) United States
(12) Patent Application Publication
(10) Pub. No.: US 2005/0170560 A1
(43) Pub. Date: Aug. 4, 2005

(54) Method of manufacturing an electronic device

(75) Inventor: Johannus Wilhelmus Weekamp, Eindhoven (NL)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: Koninklijke Philips Electronics N.V., Eindhoven (NL)

(21) Appl. No.: 10/510,878

(22) PCT Filed: Apr. 10, 2003
(86) PCT No.: PCT/IB03/01307

(30) Foreign Application Priority Data
Apr. 11, 2002 (EP) 02076427.0
Aug. 5, 2002 (EP) 02078208.2

(51) Int. Cl. H01L 21/44; H01L 21/48; H01L 21/50

(52) U.S. Cl. 438/125

(57) ABSTRACT

A method of manufacturing an electronic device (10) is proposed that comprises an insulating body (2) with at a surface a conductive pattern (1). According to the invention, a carrier (3) is provided with a first layer (4) and a second layer (5), which layers (4, 5) comprise different materials. After reshaping of the carrier (3) from the side of the second layer (5), insulating material (2) is provided at the side of the second layer (5), and the first layer (4) is removed, therewith providing the insulating body (2) with the conductive pattern (1). The reshaping may be done, for example, by bending or by forcing. The resulting body (2) is very suitable for use in modules, as part of a compact camera. Its shape may be defined with a mold.

The invention relates to a method of manufacturing an electronic device which comprises an electrically insulating body provided with a conductor pattern at a surface, and to devices manufactured in such a manner.

Modules are increasingly used as building blocks in the manufacture of electronic devices. A module is built up from an electrically insulating body provided with a conductor pattern, a number of components interconnected by means of the conductor pattern, and a protective layer. The module as a whole then performs a certain function. The use of modules is interesting for two reasons: first, individual components may require different techniques which each have their own advantages and which cannot be very well integrated into a single (semiconductor) device. Second, the module usually has a specific function and its design requires a specific expertise. Owing to the increased functionality of electronic devices, a manufacturer thereof is no longer capable of commanding all expertise required, which is an obstacle to the manufacture of a single carrier, such as a printed circuit board, with all components.

The above method is known inter alia from U.S. Pat. No. 6,087,721. In the known method, an opening is provided in an insulating body. The body is then placed on a thermally conducting layer, a metal layer in this case, and a component is placed in the opening. The component, a bipolar transistor in this case, is connected by means of bonding wires to the conductor pattern at the surface, where further components are also present. The thermally conducting layer here serves to remove excess heat away from the transistor.

It is a disadvantage of the known method that only a very limited integration in the thickness direction, i.e. perpendicular to the insulating body, can take place in the module, and where it occurs it is essentially labor-intensive and expensive. This is true, for example, for the assembly of the thermally conducting layer with the body which, if carried out on large plates, leads to separation problems. It is also true for the placement of the transistor in the opening. In addition, a separate protective layer is necessary. The module manufactured by the known method is essentially not much more than a body with a conductor pattern on which components are connected in accordance with a desired circuit.

It is accordingly an object of the invention to provide a method of the kind mentioned in the opening paragraph in which an assembly of components can take place in more than one direction.

This object is achieved in that the method comprises the steps of:
providing a carrier plate with a first side and an opposed second side, with, starting from the first side in that order, a first layer of a first mechanically deformable material and a second layer of a second material different from the first, which second material is patterned substantially in accordance with the conductor pattern and is electrically conducting;
deforming the carrier plate;
providing insulating material at the second side of the carrier plate so as to form the electrically insulating body; and
removing the first layer such that the conductor pattern becomes exposed at the surface of the body.

The method according to the invention utilizes a carrier plate with a first layer which is present during manufacture only. After this carrier plate has been deformed in a desired manner, an electrically insulating material is provided. This is preferably done in a mold, whereby the shape of the electrically insulating body is defined. Openings and cavities may also be defined during this without a separate step being necessary. The first layer is then removed, such that the conductor pattern appears at the surface of the body. The conductor pattern is accordingly provided in a flat plane in which the desired functionality is defined, and the desired shape is provided subsequently.

The device according to the invention may be realized in various modifications. First of all, the body may be manufactured first, after which components are placed. Another possibility is that prior to the provision of the insulating material one or several components are already assembled and are encapsulated in the insulating material. This may reduce the height of the device and provides an envelope without a separate protective layer having to be provided. It may be, furthermore, that the device comprises only a single component which is provided with contacts which do not lie in a single plane. Another possibility is that the carrier plate is assembled with a further substrate before being enveloped, such that a cavity is defined between the substrate and the carrier plate.

A method involving a carrier plate with a first layer, which is removed after the provision of an integrated circuit and of the insulating material, is known per se from European patent EP 1 160 858 A2. This known method, however, does not comprise a step in which the carrier plate is deformed. The first and the second layer here both comprise copper by preference, which is a material that cannot be deformed sufficiently easily. Furthermore, the total carrier plate is comparatively thick, for example 125 μm. The very fact that the carrier plate must be comparatively thin, because the major portion thereof must be capable of a ready and quick removal, makes it possible for the carrier plate to be comparatively easily deformed in the method according to the invention, in contrast to the carrier plate of the known method. In addition, there is no reason for applying any deformation to the carrier plate in the known method; the conductor pattern is used for defining the contacts of an integrated circuit. Solder can be provided at the lower side of these contacts during the placement of the circuit on a carrier. It is not desirable here for the conductor pattern to be in more than one plane.

The electrically conducting material of the second layer of the carrier plate is, for example, copper, nickel, silver, indium-tin oxide, an iron-nickel alloy, or an organic conductor. The elastic material of the first layer of the carrier plate is, for example, a thermoplastic synthetic resin such as, inter alia, polyimide, polyphenylene sulfide (PPS), and furthermore, as is known to those skilled in the art, a photoresist or a comparatively elastic metal such as aluminum. Good results were obtained with a combination of aluminum and copper, because the one material can be selectively etched with respect to the other. The first layer preferably has a greater thickness than the second layer. This is because the resolution of the patterns is dependent on the layer thickness during patterning of the second layer. If a resolution of the order of 10 to 100 μm is desired, a thickness of the same order of magnitude is required. A layer having such a thickness, however, is insufficiently strong, but for this purpose the second layer may be constructed to be thicker. Alternatively, the first layer may be present between the second layer and a third layer. The first layer then provides the etching selectivity with respect to the second layer, while the third layer safeguards the strength while serving as a temporary carrier. The first layer may also bridge stresses between the second and the third layer caused by the deformation.

If so desired, the second layer may also be provided with further layers. Such layers may be provided, for example, by thin-film processes and offer a possibility of providing the conductor pattern with vias. An attractive embodiment is, for example, the provision of a patternable dielectric material such as benzocyclobutene, a photoresist such as SU-8, or a porous low-K material, on which a second conducting layer may be provided in accordance with the desired pattern. Alternatively, the further layers may be provided as adhesive layers, in particular for providing solder or bumps.

The deformation of the carrier plate may take place in at least two manners: bending and pressing in.

In a first embodiment, the deformation takes place in that the carrier plate is bent in at least one direction so as to enclose an angle which is substantially smaller than 180°. Bending renders an effective use of especially the third dimension, i.e. in the thickness direction, possible. Strip-shaped conductors in the pattern may thus be present both in the first plane and in a second plane. A substantial space saving is realized thereby. In addition, contacts may be defined at several surfaces, which provides flexibility in the provision of components and in assembling the device together with other bodies. The strip-shaped conductors may furthermore be very narrow and still be provided on the insulating body with very good adhesion.

In a preferred embodiment, the carrier plate is bent at least once through an angle of approximately 90°. Bending through such an angle renders it possible to obtain the maximum result with the method according to the invention. Very favorable is a further embodiment in this respect in which the carrier plate is bent twice through an angle of approximately 90°. This creates a body on which components can be provided at two mutually opposed surfaces. If furthermore the insulating material is provided by means of a mold, desired shapes may be defined in the body, including openings and cavities, while at the same time conductors can be present where necessary. Thus conductors may also be provided in the cavity.

In a second embodiment, the deformation of the carrier plate takes place in that the carrier plate is pressed in from the second side of the carrier plate in desired positions such that, after the provision of the electrically insulating material, the conductor pattern projects beyond the surface of the body in the desired positions in a direction perpendicular to the surface. Recesses and projections can be provided by this embodiment with a surprisingly good accuracy, the projections arising in that the remaining portion is pressed in. The pressure could also be applied from the first side, but this leads to a lesser control of the deformation of the second layer than during pressing in from the second side. Pressing in takes place preferably by means of a die which comprises, for example, a substrate of Si with Ni/Au bumps, or a steel substrate with Ni patterns.

The recesses formed by pressing in define cavities in which components may be placed. The projections define, for example, alignment locations or adhesion locations. The latter is of particular interest if the first layer is somewhat etched prior to deformation, during which underetching of the second layer takes place. When the insulating material is subsequently provided, the conductor pattern will lie somewhat recessed in the insulating material, in recessed portions of the surface. This is sometimes favorable, for example for protecting the conductors against damage. Sometimes it is unfavorable, especially if an electrical connection to a component is realized by means of bumps. In the latter case the pressure ensures that adhesion locations arise which extend to just above the surface of the body.

It is noted that the deformation by pressing in may very well take place in addition to the deformation by bending. The pressing in renders it possible in fact to realize a deformation locally, with a resolution of the order of microns, whereas the bending relates substantially, but not exclusively, to larger scales.

In a favorable modification of the method, the second layer is patterned through a local, preferably selective removal of a portion of the second layer from the second side of the carrier plate under formation of a recess, whereupon the formation of the recess is completed by selective etching of a portion of the first layer located in the recess, during which underetching of the first layer with respect to the remaining portion of the second layer takes place. As a result of this, the insulating body extends above the conductor pattern, partly over the surface thereof. This makes the adhesion of the conductor pattern to the insulating body particularly strong, which is obviously a major advantage in particular if the width of a number of strip-shaped conductors forming part of the conductor pattern is very small.

In a further modification of the latter embodiment, the conductor pattern comprises a number of strip-shaped conductors which are each provided with a region of larger dimensions than the width of the strip-shaped conductors. In this case, the underetching of the first layer with respect to the remaining portion of the second layer is made so great that the second layer becomes free from the first layer at the areas of the strip-shaped portions of the strip-shaped conductors, whereas the second layer is still connected to the first layer at the areas of the connection regions. The strip-shaped portions of the strip-shaped conductors are subsequently entirely enveloped during the provision of the insulating material. The strip-shaped portions of the strip-shaped conductors are thus entirely enveloped in the insulating body. Said portions are accordingly well protected against mechanical damage or corrosive attacks. In addition, this modification offers the possibility of providing a further conductor crosswise over such a conductor which is (substantially entirely) enveloped by the insulating body. This offers particularly attractive possibilities substantially without detracting from the compactness of a device obtained by the method.

In a favorable embodiment, the conductor pattern comprises a number of strip-shaped conductors which are each provided with at least one region having dimensions larger than the width of the strip-shaped conductors. The region of larger dimensions is very suitable for acting as a connection region for components.

In a further modification, the strip-shaped conductors are provided at one end with respective regions serving as connection regions, and said connection regions are placed in a closed arrangement, preferably rectangular, on a first planar surface of the insulating body, a number of said strip-shaped conductors extending further to a second planar surface which encloses an angle with the first planar surface which is substantially smaller than 180°. A structure is thus realized which is very favorable for the placement of semiconductor devices. Since the conductors extend over both the first and the second surface, the space requirement is limited.

In an advantageous modification of the latter embodiment, the insulating body is provided with an opening which, when seen in projection, lies within the closed arrangement, a photosensitive semiconductor element is fastened to the insulating body with its photosensitive side facing the opening and is electrically connected to the connection regions, and an optical lens is fastened to the insulating body in the opening at a side thereof situated opposite the semiconductor element. An electronic device is thus manufactured which comprises a particularly compact camera which may be used to advantage in, for example, a mobile telephone. A particularly great demand is expected for this combination of a mobile telephone with an integrated camera.

In a further embodiment of a method according to the invention, an active or passive electronic element, such as a semiconductor element, is provided on or above the carrier plate before the insulating material is provided against the carrier plate, which element is electrically connected to the conductor pattern and is surrounded by the insulating material, which thus acts as a passivating envelope for the electronic element. A very compact electronic device is thus obtained in a particularly simple manner with an insulating body to which a number of electronic and/or semiconductor elements can be fastened at the outside, while the insulating body thereof may also comprise a number of further electronic and/or semiconductor elements.

This embodiment has among its advantages that the resulting device, in particular a semiconductor device, can be placed on a substrate by more than one side. In a particularly favorable modification, the device can be provided with a “compliant package”. This is an envelope in which the conductor pattern is such that the connection to the substrate is not determined by the location of the electric element. Furthermore, this offers the possibility of manufacturing modules whose components are first mounted in one plane, whereupon the envelope is folded into a box and may be encapsulated.

In yet another embodiment, the device may be used for medical systems. The device is in particular highly suitable for use in ultrasonic devices. The three-dimensional conductor pattern may then provide an electrical connection and possibly a partial envelope for arrays of piezoelectric elements.

In a further attractive modification of a method according to the invention, in which the recess is formed through the local, and preferably selective removal of a portion of the second layer of the carrier plate, whereupon the formation of the recess is completed through selective etching of a portion of the first layer situated in the recess, such that underetching of the first layer takes place with respect to the remaining portion of the second layer, said recess in the carrier plate is formed such that it encloses a conductor pattern comprising a number of strip-shaped conductors, of each of which both ends are provided with a connection region of larger dimensions than the width of the strip-shaped conductors, and the underetching of the first layer with respect to the remaining portion of the second layer is made so great that the second layer becomes separated from the first layer at the area of the strip-shaped portion of each strip-shaped conductor, whereas the second layer is still connected to the first layer at the areas of the connection regions. The strip-shaped portion of each strip-shaped conductor is thus entirely surrounded by the insulating body. These portions are thus well protected against mechanical damage or corrosive attacks. In addition, this modification offers the possibility of providing a further conductor which crosses such a conductor which is (substantially entirely) surrounded by the insulating body. This offers particularly attractive possibilities substantially without detracting from the compactness of a device obtained by the method.

In a further favorable modification, the carrier plate is bent a few times, preferably four times, through an angle of preferably 90°. Very compact devices with comparatively many components can be obtained in this manner. An example thereof is bending of the carrier plate into a tube which is U-shaped in cross-section, such that the connection piece between the legs of the U, on which legs the components are present, is chosen to be comparatively short and is not provided with a component. If so desired, components provided on the legs of the U-shape may be electrically interconnected. Other devices may also be formed in this manner, for example in the form of a box, which may or may not be flat when viewed in cross-section.

Preferably, aluminum is chosen for the material of the first layer of the carrier plate, and copper for the material of the second layer of the carrier plate. The best results are obtained when the thickness of the first layer of the carrier plate is chosen to be between 10 and 300 μm, preferably a thickness of approximately 30 μm, and the thickness of the second layer is chosen to be between 2 and 20 μm, preferably a thickness of approximately 10 μm. It is advisable after the formation of the insulating body to remove the entire first layer from the carrier plate. This has various advantages. The removal may take place by means of CMP (=Chemical Mechanical Polishing), or by etching, or a combination of the two techniques. Especially if the first layer of the carrier plate is comparatively thin, the (wet-chemical) etching of the first layer is a particularly attractive option, also because in this manner the first layers of two surfaces enclosing an angle with one another, preferably at right angles to one another, of a bent carrier plate can be easily simultaneously removed.

In a favorable embodiment, the carrier plate, before being bent, is given a preparatory treatment along a line in a direction approximately perpendicular to the bending direction, preferably at its rear side, so as to facilitate bending along said line. Such a treatment may consist, for example, in the provision of a preferably linear groove, which may or may not be locally interrupted, in the carrier plate.

The invention will now be explained in more detail with reference to embodiments and the drawings, in which:

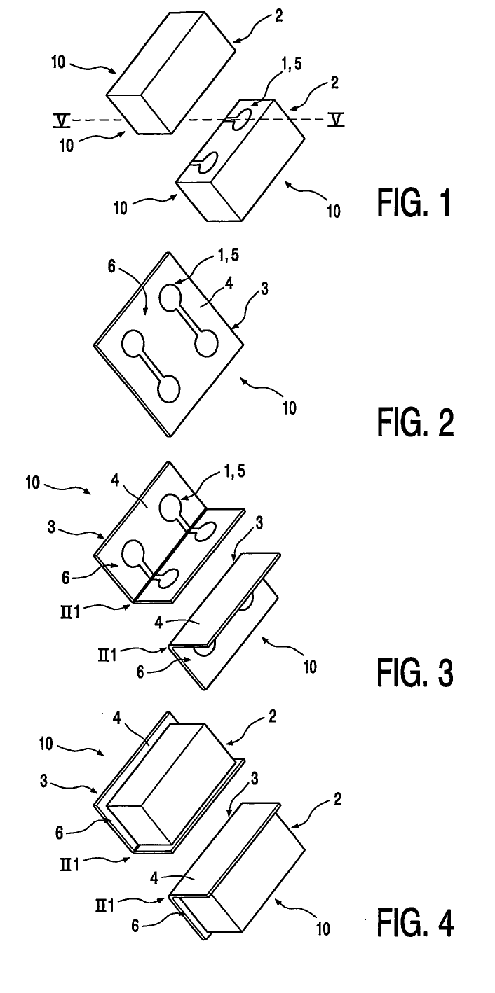

FIG. 1 shows a first electronic device manufactured by a first embodiment of a method according to the invention diagrammatically and in perspective view, in two elevations enclosing an angle of 90°,

FIGS. 2 to 4 show the device of FIG. 1 in consecutive stages of its manufacture by the first embodiment of a method according to the invention diagrammatically and in perspective view, in two elevations enclosing an angle of 90°, except for FIG. 2,

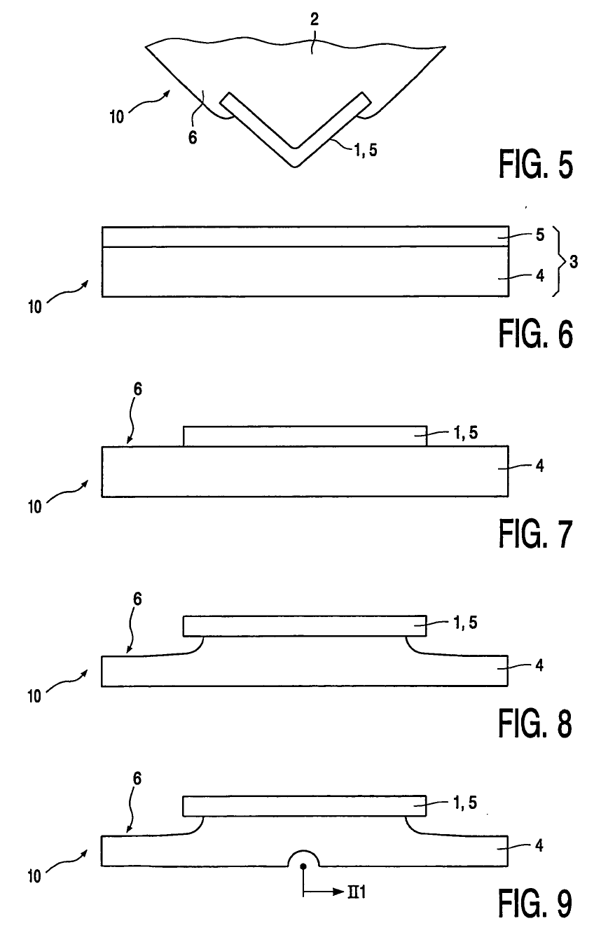

FIG. 5 shows a modification of the device of FIG. 1 in a diagrammatic cross-section taken on the line V-V in FIG. 1,

FIGS. 6 to 11 show the device of FIG. 5 in consecutive stages of its manufacture by a second embodiment of a method according to the invention in the same diagrammatic cross-section,

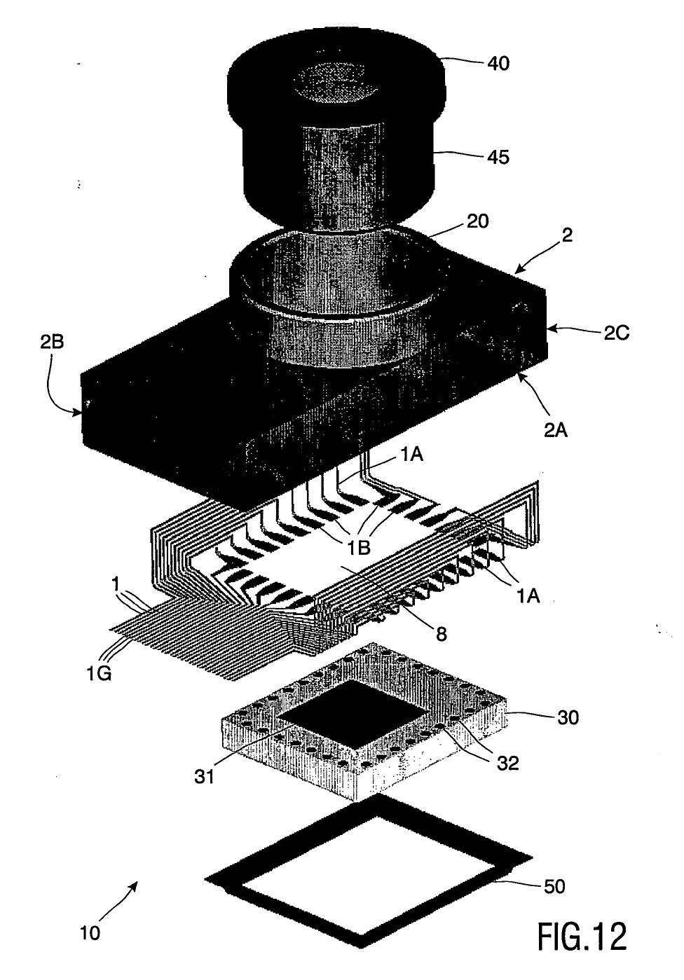

FIG. 12 is a diagrammatic, perspective, exploded view of an electronic device comprising a compact camera, manufactured by a further embodiment of a method according to the invention,

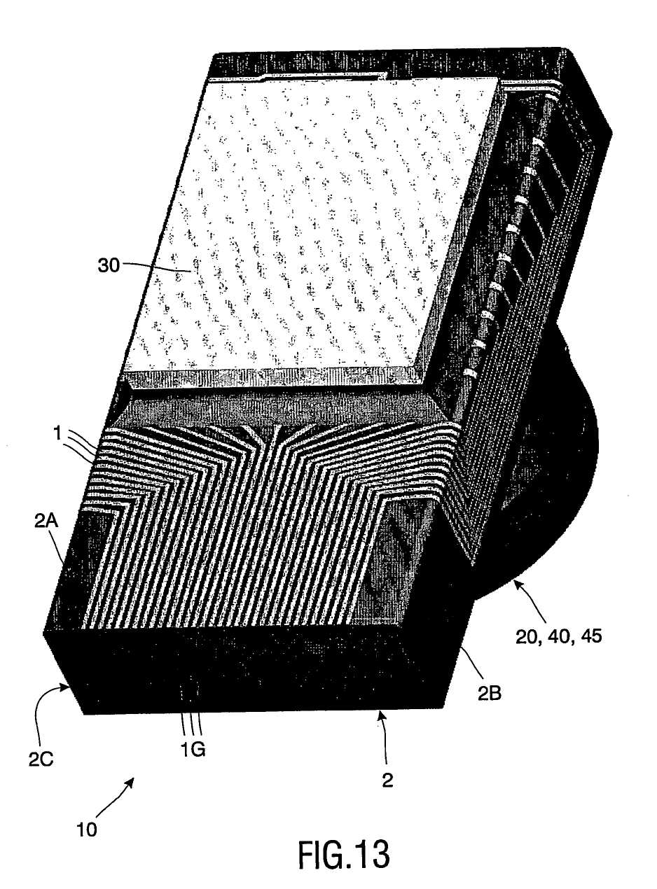

FIG. 13 is a diagrammatic, perspective, assembled view of the device of FIG. 12 rotated through an angle of 180° with respect to FIG. 12, and

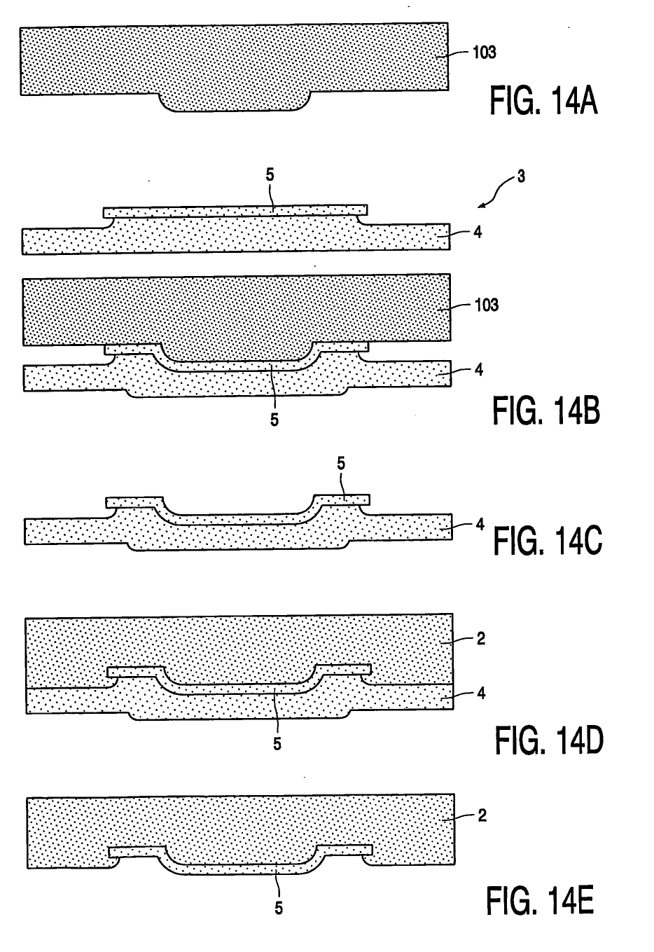

FIGS. 14A to E diagrammatically show a second embodiment of the method in cross-sections corresponding to those above.

The Figures are not drawn true to scale, and some dimensions have been particularly exaggerated for greater clarity. Corresponding regions or components have been given the same reference numerals as much as possible.

FIG. 1 shows a first electronic device manufactured by a first embodiment of a method according to the invention diagrammatically and in perspective view, in two elevations enclosing an angle of 90°. FIGS. 2 to 4 show the device of FIG. 1 in consecutive stages of its manufacture by the first embodiment of a method according to the invention, diagrammatically and in perspective view in two elevations enclosing an angle of 90°, except for FIG. 2.

The device 10 of this example comprises a simple synthetic resin block 2, made of PPS (=PolyPhenylene Sulfide) here, which is a thermoplastic material, with a dumbbell-shaped conductor pattern 1 on two mutually perpendicular side faces thereof. Such a block may be used, for example, for mounting a so-termed side-emitter diode laser on an electrically conducting base plate, such that the optical beam of the laser is perpendicular to the base plate. The half of the dumbbell-shaped conductor pattern present on a side face is then (electrically) connected to the base plate. The laser is (electrically) fastened to the other half of said pattern present on an adjoining side face which encloses an angle of 90° with the former side face. The dimensions of such a block 10 are, for example, 1×1×2 mm³.

The manufacture of such a device 10 starts with a carrier plate 3 (see FIG. 2) which comprises a first layer 4, an aluminum layer 4 in this case with a thickness of 30 μm, on which a second, electrically conducting, thinner layer 5 is present, made of copper here and having a thickness of 10 μm. Thereon, i.e. on the second layer 5, a dumbbell-shaped mask of silicon dioxide is formed by photolithography, whereupon the copper is removed from the second layer 5 outside this mask by etching with an aqueous solution of ferrichloride, such that a recess 6 is formed in the carrier plate 3, which recess is completed by means of the same etchant in that a further portion of the second layer 5 and also a portion of the first layer 4 of aluminum are removed. Then (see FIG. 3) a linear groove L is provided at the rear side of the carrier plate 3 so as to facilitate the bending of the carrier plate 3 through an angle of 90°, as is shown in FIG. 3. The device 10 (see FIG. 4) is then placed in a mold (not shown in the drawing), after which the electrically insulating body 2 is formed by injection molding in that, for example, PPS material is injection-molded against the carrier plate 3. The recess 6 is also filled up by a portion of the body 2 during this. Then so much is removed from the carrier plate 3 from the side of the first layer 4, by etching in this case, that the recess 6 filled up by a portion of the body 2 is reached. The entire first layer 4 is removed in this example. The device 10 shown in FIG. 1 is thus obtained, with an insulating body 2 having the conductor pattern 1 recessed in its surface so as to extend over two adjoining, mutually perpendicular side faces.

FIG. 5 shows a modification of the device of FIG. 1 in a diagrammatic cross-section taken on the line V-V in FIG. 1. FIGS. 6 to 11 diagrammatically show the device of FIG. 5 in consecutive stages of its manufacture by a second embodiment of a method according to the invention in a cross-section similar to that of FIG. 5. The device 10 in this example differs from that of FIG. 1 in that the dumbbell-shaped conductor pattern 1 is not just recessed into the surface of the insulating body 2, but is even partly buried therein, as is clearly visible in FIG. 5. The conductor pattern 1 as a result is securely anchored in the body 2.

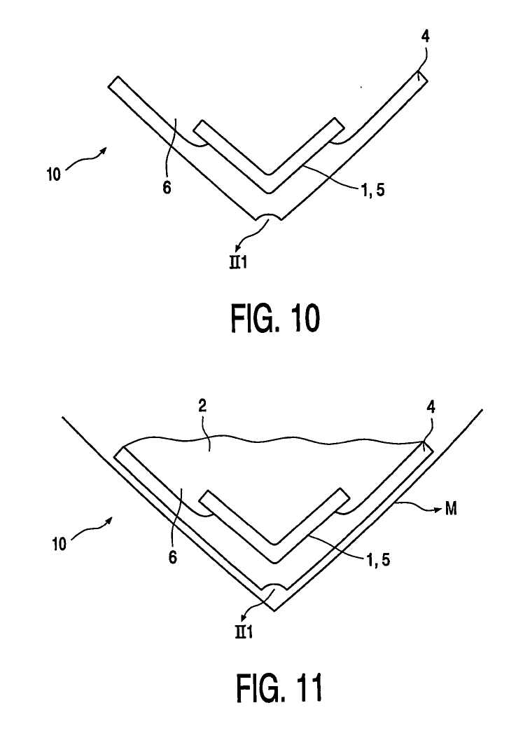

The manufacture of the device 10 of this example is largely the same as indicated above for the first example. The main difference (see FIGS. 7 and 8) lies in the fact that the recess 6 is formed in two separate steps. First (see FIG. 7) part of the second layer 5 of copper is removed, preferably selectively, whereby the first portion of the recess 6 is formed. This may be done, for example, with an aqueous solution of ferrichloride, an etchant with a comparatively low selectivity with respect to aluminum. Then a portion of the first layer of aluminum is removed by means of a different, selective etchant, such that underetching of the first layer 4 occurs with respect to the remaining portion of the second layer 5. The selective etchant for aluminum used may be, for example, (an aqueous solution of) sodium hydroxide. The provision of the linear groove L and the bending of the carrier plate (see FIGS. 9 and 10) take place in the same manner as in the first example. This is also true (see FIG. 11) for the formation of the insulating body 2 by injection molding with the use of a mold of which a portion M is shown in FIG. 11.

FIG. 12 is a diagrammatic, perspective, exploded view of an electronic device comprising a compact camera and manufactured by a further embodiment of a method according to the invention. FIG. 13 diagrammatically shows this device in perspective view and in the assembled state at an angle of 180° with respect to FIG. 12. The device 10 see, for example, FIG. 12—comprises a synthetic resin carrier body 2, made of PPS (=PolyPhenylene Sulfide) here, in which an opening 20 is present in which an optical lens 40 arranged in a cylindrical holder 45 is fastened. At the other side of the opening 20, a rectangular closed arrangement 8 of connection regions 1B present at respective ends 1A of strip-shaped conductors 1 is present on a flat surface 2A of the body 2. These conductors 1 extend directly to the end of the surface 2A at one side of the closed arrangement 8, where accordingly the other ends 1C of the strip-shaped conductors 1 are present. The strip-shaped conductors 1 present at the other three sides of the closed shape 8 run partly over the surface 2A, but for the rest partly over two side faces 2B, 2C of the body 2 which are perpendicular to the surface 2A. The conductors 1 present at the rear of the closed arrangement 8 then distribute themselves over the two side faces 2B, 2C. The device 10 in this example can be particularly compact as a result of this. In addition, its manufacture is simple and inexpensive.

Furthermore, a photosensitive semiconductor element 30, a so-called CCD (=Charge Coupled Device) or CMOS (=Complementary Metal Oxide Semiconductor) sensor 30, is fastened against the surface 2A of the body 2 by means of a frame 50. The photosensitive region 31A of the sensor 30 is then present opposite the opening 20 in the body 2, and the connection regions 32 of the sensor 30 are fastened with electrical conduction to connection regions 1B of the strip-shaped conductors 1 lying in the closed arrangement 8. FIG. 13 shows the device 10 once more from a different side, in the assembled state this time. The signals from the device 10 may be taken off and/or passed on at the ends 1C of the conductors 1, for example within a mobile telephone (not shown), for which the device 10 is particularly suitable because of its compactness in three directions.

The device 10 of this example can be manufactured by a modification of one of the methods according to the invention discussed above. The main difference here is that the carrier plate 3 of this example is bent not once through 90°, but at two sides through 900 so as to form the planar side face 2A of the body 2 as well as the two planar side faces 2B, 2C, which each enclose an angle of 90° with the side face 2A. Various modifications are possible, furthermore, for example in that the carrier plate 3 is bent in three or four locations partly through 90°.

FIG. 14 shows a number of consecutive steps in a second embodiment of the method, where the deformation of the carrier plate 3 takes place by pressing the latter in. FIG. 14A shows the initial situation. Recesses 6 have been provided in the carrier plate 3 for patterning the second layer 5 and, in this embodiment, an etchant was used for partially etching the first layer 4, such that underetching of the conductor pattern in the second layer 5 arises. Subsequently a die 103, for example formed by Ni/Au bumps on a Si substrate, is brought into contact with the carrier plate 3, as shown in FIG. 14B, during which the carrier plate 3 lies on a hard surface. The die 103 is preferably at the side having the second layer 5. Alternatively, a second die or a second portion of the die may be present at the side having the first layer 4.

After pressing in, the die is removed again, as is shown in FIG. 14C. Insulating material is subsequently provided, as shown in FIG. 14D, and the first layer 4 is removed, as shown in FIG. 14E. The result is a body of which the second layer 5 projects from the surface in the pressed-in locations. Tests have shown that the pressed-in locations may have various shapes, such as round, square, annular, and elongate. The pattern present in the die 103 is substantially transferred to the second layer 5 in a one-to-one ratio, and a widening of the projection occurs which is approximately equal to twice the thickness of the second layer 5.

The invention is not limited to a method as described in the embodiment, since many variations and modifications are possible to those skilled in the art within the scope of the invention. Thus devices can be manufactured with different geometries and/or different dimensions. It is also possible to use alternative materials for the carrier plate, i.e. for the layers forming part thereof. Furthermore, the insulating body may also be made from various alternative materials such as (a slurry of) a ceramic material or an epoxy resin material.

It is further noted that a large number of devices can be manufactured simultaneously by the method according to the invention, whereas the example only describes and depicts the manufacture of a single device. Conceivable are carrier plates which are present within a so-termed lead frame and which are fastened thereto in two points, for example at the two extremities of the bending line L. Individual semiconductor devices may then be obtained by a mechanical separation technique such as sawing, cutting, or breaking.

It is emphasized once more that further electronic and/or semiconductor components may be provided against or inside the device. These components may be discrete, or semi-discrete, or integrated with one another.

It is finally noted that it is necessary for the conductors to be provided with widened portions at given distances if the strip-shaped conductors are to be entirely surrounded by the synthetic resin envelope. These widened portions need not necessarily be at the ends. The distances between the widened portions are chosen such that on the one hand the strip-shaped conductor is not detached during underetching, but on the other hand that the strength of the portion of each strip-shaped conductor lying between two widened portions is sufficiently great, so that it is not damaged, for example by the material of the insulating body during the formation thereof.

1. A method of manufacturing an electronic device which comprises an electrically insulating body provided with a conductor pattern at a surface, said method comprising the steps of:
providing a carrier plate with a first side and an opposed second side, with, starting from the first side in that order, a first layer of a first mechanically deformable material and a second layer of a second material different from the first, which second material is patterned substantially in accordance with the conductor pattern and is electrically conducting;
deforming the carrier plate;
providing insulating material at the second side of the carrier plate so as to form the electrically insulating body; and
removing the first layer such that the conductor pattern becomes exposed at the surface of the body.

2. A method as claimed in claim 1, characterized in that the deformation takes place by bending of the carrier plate in at least one direction so as to enclose an angle which is substantially smaller than 180°.

3. A method as claimed in claim 1, characterized in that the deformation of the carrier plate takes place in that the carrier plate is pressed in from the second side of the carrier plate in desired positions by means of a die such that, after the provision of the electrically insulating material, the conductor pattern projects beyond the surface of the body in the desired positions in a direction perpendicular to the surface.

4. A method as claimed in claim 1, characterized in that the second layer is patterned through a local, preferably selective removal of a portion of the second layer from the second side of the carrier plate under formation of a recess, whereupon the formation of the recess is completed by selective etching of a portion of the first layer located in the recess, during which underetching of the first layer with respect to the remaining portion of the second layer takes place.

5. A method as claimed in claim 4, characterized in that
the conductor pattern comprises a number of strip-shaped conductors which are each provided with a region of larger dimensions than the width of the strip-shaped conductors, and
the underetching of the first layer with respect to the remaining portion of the second layer is made so great that the second layer becomes free from the first layer at the areas of the strip-shaped portions of the strip-shaped conductors, whereas the second layer is still connected to the first layer at the areas of the connection regions, whereupon the strip-shaped portions of the strip-shaped conductors are entirely enveloped during the provision of the insulating material.

6. A method as claimed in claim 1, characterized in that the conductor pattern comprises a number of strip-shaped conductors which are each provided with at least one region having dimensions larger than the width of the strip-shaped conductors.

7. A method as claimed in claim 6, characterized in that the strip-shaped conductors are provided at one end with respective regions serving as connection regions, and said connection regions are placed in a closed arrangement, preferably rectangular, on a first planar surface of the insulating body, a number of said strip-shaped conductors extending further to a second planar surface which encloses an angle with the first planar surface which is substantially smaller than 180°.

8. A method as claimed in claim 1, characterized in that a thickness of between 10 and 300 μm is chosen for the first layer of the carrier plate and a thickness of between 2 and 20 μm for the second layer.

9. A method as claimed in claim 1, characterized in that an electronic element is provided on or above the carrier plate, at the second side thereof, before the insulating material is provided against the carrier plate, which element is electrically connected to the conductor pattern and is surrounded by the insulating material which thus acts as a passivating envelope for the electronic element.

10. A method as claimed in claim 1, characterized in that after the removal of the first layer at least one electrical component is fastened to the electrically insulating body, such that connection regions of the component are connected with electrical conduction to the conductor pattern of the body.

11. An electronic device comprising an electronic element and an electrically insulating body provided with a conductor pattern, characterized in that the insulating body has an enclosed angle which is substantially smaller than 180°, thus defining a first and a second surface, the conductor pattern extending over said first and second surface.

12. An electronic device as claimed in claim 11, wherein the insulating body provided with a conductor pattern is provided with an opening, on the two sides of which a photosensitive semiconductor element and an optical lens, respectively, are fastened to the insulating body.

13. An electronic device comprising an electronic element and an electrically insulating body provided with a conductor pattern, characterized in that the conductor pattern projects beyond the surface of the body in desired positions in a direction perpendicular to the surface.
